(19) United States
(12) Patent Application Publication
(10) Pub. No.: US 2026/0213752 A1
(43) Pub. Date: Jul. 23, 2026

(54) BUS TRAINING USING MULTIPLE FLIP-FLOPS AND CLOCK SIGNALS

(71) Applicant: Micron Technology, Inc., Boise, ID (US)

(72) Inventors: Nicole Kang, Atlanta, GA (US); Jaeil Kim, Atlanta, GA (US); Hiroshi Akamatsu, Boise, ID (US)

(21) Appl. No.: 19/450,175

(22) Filed: Jan. 15, 2026

Related U.S. Application Data
(60) Provisional application No. 63/747,661, filed on Jan. 21, 2025.

(51) Int. Cl. H03K 19/0185; H03K 19/21

(52) U.S. Cl. CPC H03K 19/01855; H03K 19/21

(57) ABSTRACT

During a command bus training, the bus training circuitry can receive data from a bus and latch the data at the first plurality of flip-flops. The bus training circuitry can also provide the data from the first plurality of flip-flops to the XOR circuitry and provide the data from the XOR circuitry to the second plurality of flip-flops. The bus training circuitry can further latch the data at the second plurality of flip-flops and sample the data from the second plurality of flip-flops for training of a timing of the bus.

### PRIORITY INFORMATION

This Application claims the benefits of U.S. Provisional Application Number 63/747,661, filed on January 21, 2025, the contents of which are incorporated herein by reference.

### TECHNICAL FIELD

The present disclosure relates generally to semiconductor memory and methods, and more particularly, to apparatuses, systems, and methods for performing bus training using multiple flip-flops and clock signals

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 is a block diagram of a computing system in accordance with a number of embodiments of the present disclosure.

FIG. 2A illustrates a block diagram of bus training circuitry in accordance with a number of embodiments of the present disclosure.

FIG. 2B illustrates a block diagram of bus training circuitry in accordance with a number of embodiments of the present disclosure.

FIG. 3 is a timing diagram that illustrates data windows in accordance with a number of embodiments of the present disclosure.

FIG. 4 illustrates an example flow diagram of a method for performing bus training in accordance with a number of embodiments of the present disclosure.

FIG. 5 illustrates an example machine of a computer system within which a set of instructions, for causing the machine to perform any one or more of the methodologies discussed herein, can be executed.

### DETAILED DESCRIPTION

Systems, apparatuses, and methods related to performing bus training using multiple flip-flops and clock signals are described. In a number of examples, a memory device can include bus training circuitry. The bus training circuitry can include a first plurality of flip-flops, a second plurality of flip-flops, and XOR circuitry. The XOR circuitry can be coupled to the first plurality of flip-flops and the second plurality of flip-flops. The bus training circuitry can perform sampling of the data provided by a bus coupled to the memory device to determine whether the data provided by via the bus can be captured at the memory device. The bus training circuitry can receive the data from a bus. The bus training circuitry can latch the data at a first plurality of flip-flops. The bus training circuitry can provide the data from the first plurality of flip-flops to the XOR circuitry. The bus training circuitry can provide the data from the XOR circuitry to the second plurality of flip-flops. The bus training circuitry can latch the data at the second plurality of flip-flops. The bus training circuitry can sample the data from the second plurality of flip-flops for training of a timing of the bus.

In previous approaches, a timing of a bus can be trained. The bus can be, for example, a command/address (CA) bus. The CA bus can be configured to receive and provide commands and/or address data. A memory device and/or a CA bus can be placed in a CA training mode (CATM). The memory device and/or the CA bus can be placed in the CATM after the CA signals (e.g., CA data) are sampled at the memory device. The CA signals can be samples when CS_n is asserted at a CA pad location. As used herein, a CA pad can include a physical interface between a bus and the memory device. The pads of the memory device can be configured to receive CA signals and/or other signals such as the CS_n (e.g., CS_n signal).

The CA signals can be processed by a plurality of XOR gates. The output of the XOR gates can transition every 4 clock cycle time (tCK) cycles. Given that the tCK is divided into even and odd clocks, the transition rate of the output of the XOR gates is 2 tCK cycles. Because the transition rate of the output of the XOR gates is 2 tCK cycles, the XOR gate output windows is also 2 tCK. Sampled clock signals can be used to capture the output signals (e.g., output data) of the XOR gates. The sampled clock signals can be used on a flip-flop to produce the CATM output values which can be used to train the timing of the bus. As used herein, capturing the CATM output values can also be described as sampling data provided by the bus.

The sampled clock signals can be aligned to XOR chain timing which is decoded with a CATM enable signal and a combination of even clock signals (CSE) and odd clock signals (CSO). The XOR chain timing describes a duration of time used to process data using a plurality of XOR gates.

Due to the routing differences between the CA signals and process, voltage, and temperature (PVT) variations, skewness can happen between CA signals at the CA pad locations and the CA signals as they are received by the memory device. As used herein, skewness can describe the time difference between two signals. For example, a first signal can be skewed compared to a second signal if the first signal is received or latched at a different time than the second signal is received or latched due to a delay experienced in generating the second signal from the first signal. For example, skewness can happen between first CA signals and second CA signals due to the delay experienced by the first CA signals as they pass through XOR gates to generate the second CA signals.

Skewness between CA signals can interfere with the sampling of the CA signals. For example, a data window at flip-flops can be used to sample the CA signals that are stored in the flip-flops. If the CA signals are received and/or latched in the flip-flops at times that do not coincide with the data window due to the signals being delayed, then the signals may not be sampled.

In some previous approaches, flip-flops can be used to minimize the delay that the CA signals experience. For example, a first clock signal can align the CA signals at the newly introduced flip-flops (e.g., first flip-flops). The first clock signal can be faster than a second clock signal by an amount equal to a delay experienced by the CA signals. The second clock signal can be used to latch the CA signals in second flip-flops. The use of the first clock signal and the second clock signal can allow for a data window to be used such that the CA signals can be sampled. For example, the first clock signal can be used at the first flip-flops to widen the data window to allow for a second clock signals to be used to sample the CA signals at the second flip-flops.

As used herein, the term “bus training” refers to a procedure of establishing a timing parameter for correctly receiving signaling over a bus. Further, as used herein the term command bus training (CBT) refers to a bus training operation performed on a command bus.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

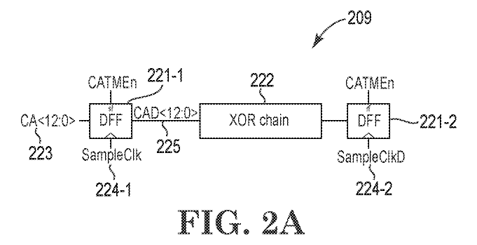

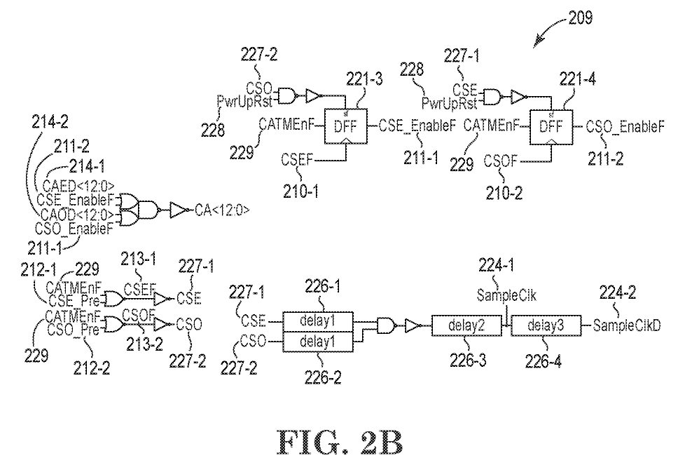

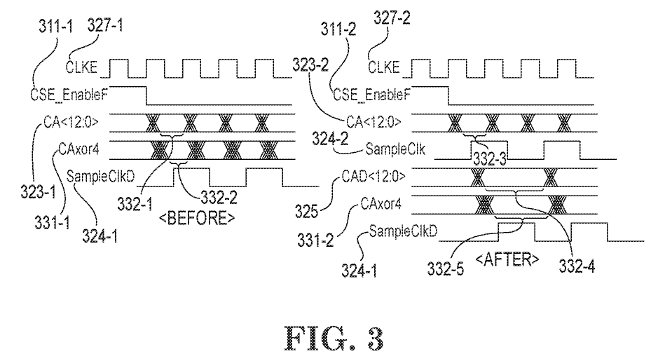

The figures herein follow a numbering convention in which the first digit or digits correspond to the drawing figure number and the remaining digits identify an element or component in the drawing. Similar elements or components between different figures may be identified by the use of similar digits. For example, 223 may reference element “23” in FIG. 2, and a similar element may be referenced as 323-1 in FIG. 3.

Analogous elements within a Figure may be referenced with a hyphen and extra numeral or letter. See, for example, elements 323-1, 323-2 in FIG. 3. Such analogous elements may be generally referenced without the hyphen and extra numeral or letter. For example, elements 323-1, 323-2, may be collectively referenced as 323. As used herein, the designators “N”, particularly with respect to reference numerals in the drawings, indicates that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

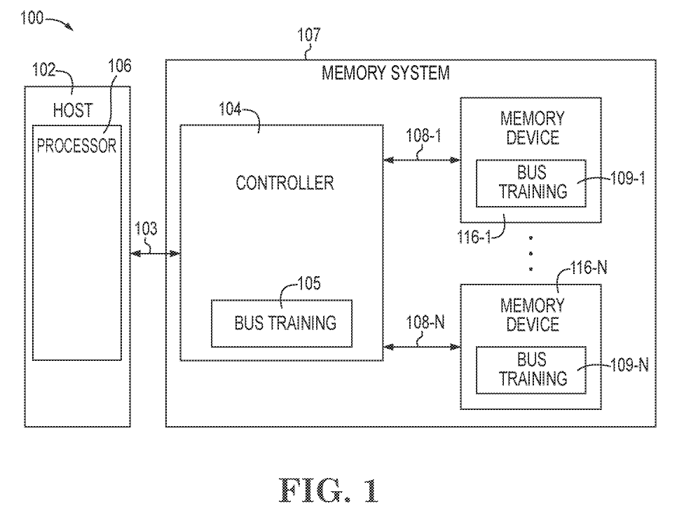

FIG. 1 is a block diagram of a computing system 100 in accordance with a number of embodiments of the present disclosure. The computing system 100 includes a host 102, a processor 106, a memory system 107, a controller 104, and memory devices 116-1, …, 116-N, which might also be separately considered an “apparatus.” The memory devices 116-1, …, 116-N and the controller 104 can collectively be referred to as a memory system 107.

The host 102 can include host memory and a central processing unit (e.g., the processor 106). The host 102 can be a host system such as a personal laptop computer, a desktop computer, a digital camera, a smart phone, a memory card reader, and/or internet-of-thing enabled device, among various other types of hosts, and can include a memory access device (e.g., a processor and/or processing device). One of ordinary skill in the art will appreciate that “a processor” can intend one or more processors, such as a parallel processing system, a number of coprocessors, etc.

The host 102 can include a system motherboard and/or backplane and can include the processing resource 106 (e.g., one or more processors, microprocessors, or some other type of controlling circuitry) also referred to as a processor 106. Although the host 102 is shown as comprising a single processing resource 106, the host 102 can comprise a plurality of processing resources. The system 100 can include separate integrated circuits or the host 102, the processor 103, the memory controller 104, and/or the memory devices 116 can be on the same integrated circuit. The system 100 can be, for instance, a server system and/or a high-performance computing (HPC) system and/or a portion thereof.

As illustrated in FIG. 1, the processor 106 can be coupled to the controller 104 via an interface 103. The interface 103 can be any type of communication path, bus, or the like that allows for information to be transferred between the host 102 and the controller 104. Non-limiting examples of interfaces can include a peripheral component interconnect (PCI) interface, a peripheral component interconnect express (PCIe) interface, a serial advanced technology attachment (SATA) interface, and/or a miniature serial advanced technology attachment (mSATA) interface, among others. However, in at least one embodiment, the interface 103 is a PCIe 5.0 interface that is compliant with the compute express link (CXL) protocol standard. Accordingly, in some embodiments, the interface 103 can include a flexible bus interconnect and use CXL protocol layers including CXL.io and CXL.mem and can support transfer speeds of at least 32 gigatransfers per second.

The controller 104 can control performance of a memory operation for an access command received from the host 102. The memory operation can be a memory operation to read data (in response to a read request from the host) from or an operation to write data (in response to a write request from the host) to one or more memory devices 116.

In some embodiments, the controller 104 can be a compute express link (CXL) compliant controller. The host interface (e.g., the front-end portion of the controller 104) can be managed with CXL protocols and be coupled to the host 102 via an interface configured for a peripheral component interconnect express (PCIe) protocol. CXL is a high-speed central processing unit (CPU)-to-device and CPU-to-memory interconnect designed to accelerate next-generation data center performance. CXL technology maintains memory coherency between the CPU memory space and memory on attached devices, which allows resource sharing for higher performance, reduced software stack complexity, and lower overall system cost. CXL is designed to be an industry open standard interface for high-speed communications, as accelerators are increasingly used to complement CPUs in support of emerging applications such as artificial intelligence and machine learning. CXL technology is built on the PCIe infrastructure, leveraging PCIe physical and electrical interfaces to provide advanced protocol in areas such as input/output (I/O) protocol, memory protocol (e.g., initially allowing a host to share memory with an accelerator), and coherency interface.

The controller 104 can be coupled to the memory devices 116 via channels 108. The channels 108 can also be referred to as buses 108. The channels 108 can include various types of data buses, such as a sixteen-pin data bus and a two-pin data mask inversion (DMI) bus, among other possible buses. In some embodiments, the channels 108 can be part of a physical (PHY) layer. As used herein, the term “PHY layer” generally refers to the physical layer in the Open Systems Interconnection (OSI) model of a computing system. The PHY layer may be the first (e.g., lowest) layer of the OSI model and can be used to transfer data over a physical data transmission medium. The channels 108 can include, for example, a CA bus.

The memory device(s) 116 can provide main memory for the computing system 100 or could be used as additional memory or storage throughout the computing system 100. The memory devices 116 can be various/different types of memory devices. For instance, the memory device can include RAM, ROM, DRAM, SDRAM, PCRAM, RRAM, and flash memory, among others. In embodiments in which the memory device 116 includes persistent or non-volatile memory, the memory device 116 can be flash memory devices such as NAND or NOR flash memory devices. Embodiments are not so limited, however, and the memory device 116 can include other non-volatile memory devices such as non-volatile random-access memory devices (e.g., non-volatile RAM (NVRAM), ReRAM, ferroelectric RAM (FeRAM), MRAM, PCRAM), “emerging” memory devices such as a ferroelectric RAM device that includes ferroelectric capacitors that can exhibit hysteresis characteristics, a memory device with resistive, phase-change, or similar memory cells, etc., or combinations thereof.

As an example, a FeRAM device can include ferroelectric capacitors and can perform bit storage based on an amount of voltage or charge applied thereto. In such examples, relatively small and relatively large voltages allow the ferroelectric RAM device to exhibit characteristics similar to normal dielectric materials (e.g., dielectric materials that have a relatively high dielectric constant) but at various voltages between such relatively small and large voltages the ferroelectric RAM device can exhibit a polarization reversal that yields non-linear dielectric behavior.

As another example, an array of non-volatile memory cells, such as resistive, phase-change, or similar memory cells, can perform bit storage based on a change of bulk resistance, in conjunction with a stackable cross-gridded data access array. Additionally, in contrast to many flash-based memories, the non-volatile memory can perform a write in-place operation, where a non-volatile memory cell can be programmed without the non-volatile memory cell being previously erased.

One example of memory devices 116 is dynamic random access memory (DRAM) operated according to a protocol such as low-power double data rate (LPDDRx), which may be referred to herein as LPDDRx DRAM devices, LPDDRx memory, etc. The “x” in LPDDRx refers to any of a number of generations of the protocol (e.g., LPDDR5). In at least one embodiment, at least one of the memory devices 116-1 is operated as an LPDDRx DRAM device with low-power features enabled and at least one of the memory devices 116-N is operated an LPDDRx DRAM device with at least one low-power feature disabled. In some embodiments, although the memory devices 116 are LPDDRx memory devices, the memory devices 116 do not include circuitry configured to provide low-power functionality for the memory devices 116 such as a dynamic voltage frequency scaling core (DVFSC), a sub-threshold current reduce circuit (SCRC), or other low-power functionality providing circuitry. Providing the LPDDRx memory devices 116 without such circuitry can advantageously reduce the cost, size, and/or complexity of the LPDDRx memory devices 116. By way of example, an LPDDRx memory device 116 with reduced low-power functionality providing circuitry can be used for applications other than mobile applications (e.g., if the memory is not intended to be used in a mobile application, some or all low-power functionality may be sacrificed for a reduction in the cost of producing the memory).

The controller 104 can further include a bus training component 105. Although not shown in FIG. 1 so as to not obfuscate the drawings, the bus training component 105 can include various circuitry to facilitate performance of operations described herein. For example, the bus training component 105 can perform those operations associated with a bus training. As used herein, the term “bus training” refers to a procedure of establishing a timing parameter for correctly receiving signaling over a bus (e.g., buses 108).

The bus training component 105 can initiate a bus training (alternatively referred to as “bus training operation”, “bus training procedure”, etc.) by issuing commands (e.g., mode register write commands) to the memory devices 116 and subsequently sending (e.g., transmit) test signals over a bus (e.g., the buses 108), to one or more memory devices 116. The channels 108 can also be referred to as CA buses 108 and the test signals can be alternatively referred to as CA signals in this example. During bus training, each memory device 116 samples and aligns the CA signals to ensure proper synchronization and reduce skew, which arises from routing delays, process variations, and PVT (Process, Voltage, Temperature) changes. By passing the sampled signals through XOR chains and aligning their timing, the signals can be stable and valid within the defined data window for reliable decoding.

The memory device 116 includes a bus training circuitry 109 (e.g., a bus training circuitry 109-1 in the memory device 116-1 and a bus training circuitry 109-N in the memory device 116-N), which can coordinate bus training procedure to be performed on memory device 116.

As used herein, the term “substantially” means that the characteristic need not be absolute, but is close enough so as to achieve the advantages of the characteristic. For example, “substantially simultaneously” is not limited to operations that are performed absolutely simultaneously and can include timings that are intended to be simultaneously but due to manufacturing limitations may not be precisely simultaneously.

FIG. 2A illustrates a block diagram of bus training circuitry 209 in accordance with a number of embodiments of the present disclosure. The bus training circuitry 209 can include a flip-flop 221-1 and a flip-flop 221-2 (e.g., DFF). The bus training circuitry 209 can also include XOR circuitry 222 which can also be referred to as an XOR chain 222.

The bus training circuitry 209 can receive the CA signals 223 (e.g., CA<12:0>). The CA signals 223 can be received from a host (e.g., the host 102 of FIG. 1). For example, the CA signals 223 can be received from a bus training component (e.g., the bus training component105 of FIG. 1) of a controller (e.g., the memory controller 104 of FIG. 1). The controller can receive the CA signals 223 from the host (e.g., the host 102 of FIG. 1). The CA signals 223 can be test signals which can be used to train a timing of the CA bus (e.g., the buses 108 of FIG. 1).

The flip-flops 221-1, 221-2 and the XOR chain 222 can be used to sample the CA signals 223. The flip-flops 221-1, 221-2 can be referred to as flip-flops 221. The flip-flops 221 can be delay flip-flops (DFF) which are also referred to as data flip-flops (DFF). Each of the flip-flops can be used to store a single bit of data. The output of the flip-flops 221 can depend on the input and a clock input (e.g., “SampleClk” 224-1 and/or “SampleClkD” 224-2), which describes a clock signal used to convey timing information.

The flip-flops 221-1 can receive the CA signals 223, a clock signal 224-1 (shown as “SampleClk” in FIG. 2A and alternatively referred to as “first sample clock”), and the CATMEn signal. The CATMEn signal enables the operation of the flip-flops 221-1, allowing the CA signals 223 to be sampled and latched during its active period. For example, while the flip-flops 221-1 are enabled, the flip-flops 221-1 sample (e.g., each bit of) the CA signals 223 based on the clock signal 224-1. The flip-flops 221-1 can generate an output 225 (e.g., CAD<12:0>), which can comprise the captured CA signals 223 such that the output 225 is CA signals that are timed to a leading (e.g., rising) edge of the sample clock 224-1.

The CA signals 223 can transition (e.g., change its logic state) every 2 tCK as they are received at the bus training circuitry 209. Although the flip-flops 221 and the XOR chain 222 are described as being in the bus training circuitry 209, the flip-flops 221 and the XOR chain 222 can be in a command decoder (not shown) of the memory devices. The CA signals 223 transitioning describes an opportunity for the CA signals 223 to change and/or to be updated. The 2 tCK describes the frequency at which the CA signals 223 transition. The CA signals 223 can transition at a rate of 2 tCK because clock signals used to provide the CA signals 223 can be divided into even clock signals and odd clock signals.

In previous approaches where the flip-flops 221-1 were not implemented (e.g., to the input of the XOR chain 222), the XOR chain 222 outputs the CA signals 223 at a transition rate of 2tCK, while sampling occurred at a transition rate of 4tCK. The 2tCK data window may have been insufficient for reliably sampling the CA signals 223 at the flip-flop 221-2 due to the narrow timing margin associated with the 2tCK transition rate. As used herein, the term “transition rate” refers to the rate at which a signal changes its logic state, such as transitioning from high to low or low to high.

To address these limitations, the flip-flops 221-1 can be implemented such that the flip-flops 221-1 sample the CA signals 223 at a rate that is analogous to the rate at which the input signal is sampled at and output from the XOR chain 222. The output 225 can also be referred to as a CAD signal 225 (e.g., CAD<12:0>). The CAD signal 225 can have a transition rate of 4 tCK because the sample clock 224-1 has a transition rate of 4 tCK. The CAD signal 225 can have a transition rate of 4 tCK even though the CA signal 223 has a transition rate of 2 tCK because the sample clock signal 224-1 has a transition rate of 4 tCK. The CAD signal 225 can provide the same data as the CA signal 223 while having slower transition rate (e.g.,4 tCK vs. 2 tCK). The CAD signal 225 can have a transition rate of 4 tCK because it is driven by the sample clock 224-1, which also has a transition rate of 4 tCK. Despite the CA signal 223 having a transition rate of 2 tCK, the CAD signal 225 adopts a transition rate of 4 tCK due to being sampled by the sample clock signal 224-1 having a transition rate of 4 tCK.

The XOR chain 222 can comprise a plurality of XOR gates coupled in series. For example, the output of one of the XOR gates of the XOR chain 222 can be an input to a different one of the XOR gates of the XOR chain 222. Other configurations of logic gates can comprise the XOR chain 222.

The XOR chain 222 can receive the CAD signals 225 having a transition rate of 4 tCK. The output of the XOR chain 222 can be delayed in time compared to the receipt of the CAD signals 225. However, both of the CAD signals 225 and the output of the XOR chain 222 can have a transition rate of 4 tCK. The output of the XOR chain 222 can be provided to the flip-flops 221-2. The flip-flops 221-2 can receive the output of the XOR chain 222, a clock signal 224-1 (shown as “SampleClkD” in FIG. 2A and alternatively referred to as “second sample clock”), and the CATMEn signal. The CATMEn signal enables the operation of the flip-flops 221-2, allowing the output of the XOR chain 222 to be sampled and latched during its active period. For example, while the flip-flops 221-2 are enabled, the flip-flops 221-2 sample (e.g., each bit of) the output of the XOR chain 222 based on the clock signal 224-2.

The output of the flip-flops 221-2 can have a transition rate of 4 tCK. The output of the flip-flops 221-2 can be sampled utilizing a 4 tCK data window. Sampling the output of flip-flops 221-2 at a 4tCK rate ensures a wider data window, providing greater timing margin and reducing the risk of errors compared to sampling at a 2tCK rate.

The clock signals 224-1, 224-2 can be delayed from each other. For example, the clock signal 224-2 can be delayed as compared to the clock signal 224-1. The delay of the clock signal 224-2 as compared to the clock signal 224-1 can account for the delay experienced by the CAD signals 225 as they are processed by the XOR chain 222. The delay in the clock signals 224-1, 224-2 can account for the skewness of the CA signals 223 and the CAD signals 225 as they are received at the flip-flops 221-1 and the flip-flops 221-2, respectively. The clock signals 224-1 can align with the flip-flops 221-1 while the clock signal 224-2 align with the flip-flops 221-2 such that the transition rate of the CA signals 223 and the CAD signals 225 align with the data window. FIG. 3 shows the aligning of the data window and the clock signals 224-1, 224-2.

FIG. 2B illustrates a block diagram of bus training circuitry 209 in accordance with a number of embodiments of the present disclosure. The training circuitry 209 can include flip flops 221-3, 221-4 and delay elements 226-1, 226-2, 226-3, 226-4. The delay elements 226-1, 226-2, 226-3, 226-4 can be referred to as delay elements 226. The delay elements 226 can be used to generate the clock signals 224-1, 224-2. The clock signals 224-1, 224-2 can be referred to as clock signals 224.

The flip-flops 221-3, 221-4 can be used to generate the CSE_EnableF signal 211-1 and the CSO_EnableF signal 211-2. The CSE_EnableF signal 211-1 can indicate that the even bits of the CA signals 223 are enabled while the CSO_EnableF signal 211-2 can indicate that the odd bits of the CA signals 223. A NAND gate can receive an odd clock signal 227-2 and a power signal 228 (e.g., PwrUpRst). The output of the NAND gate can be provided to a NOT gate. The output of the NOT gate can be provided to the flip-flop 221-3. The flip-flop 221-3 can also receive the CATMEnF 229 and a CSEF signal 210-1. The CSEF signal 210-1 is described below.

A NAND gate can receive an even clock signal 227-1 and a power signal 228 (e.g., PwrUpRst). The output of the NAND gate can be provided to a NOT gate. The output of the NOT gate can be provided to the flip-flop 221-4. The flip-flop 221-4 can also receive the CATMEnF 229 and a CSOF signal 210-2. The CSOF signal 210-2 is described below.

The CSE_EnableF signal 211-1 and the CSO_EnableF signal 211-2 can be used to generate the CA signals 223. For example, the CAED signals 214-1 (e.g., CAED<12:0>), the CSE_EnableF signals 211-2, the CAOD signals 214-2 (e.g., CAOD<12:0>), and the CSO_EnableF signals 211-1 can be utilized to generate the CA signals 223. The CAED signals 214-1 and the CAOD signals 214-2 represent the data provided at the pads of the memory devices. The CAED signals 214-1 and the CSE_EnableF signal 211-2 can be provided to a first OR gate. The CAOD signals 214-2 and the CSO_EnableF signal 211-1 can be provided to a second OR gate. The output of the first OR gate and the second OR gate can be provided to a NAND gate. The output of the NAND gate can be provided to a NOT gate. The output of the NOT gate can be the CA signals 223.

In various instances, the CSE signal 227-1 and the CSO signal 227-2 can be generated using the CATMEnF signal 229, the CSE_Pre signal 212-1 and the CSO_Pre signal 212-2. The CSE_Pre signal 212-1 and the CSO_Pre signal 212-2 are CS signals received from a command decoder. The CSE_Pre signal 212-1 and the CSO_Pre signal 212-2 can be enabled when CATMEn is enabled. The CSE_Pre signal 212-1 and the CSO_Pre signal 212-2 can be used to generate the clock signals 224-1, 224-2 which are provided to the flip-flops 221-3, 221-4. The CATMEnF signal 229 and the CSE_Pre signal 212-1 can be provided to a first NOR gate. The output of the first NOR gate can be a CSEF signal 213-1. The CATMEnF signal 229 and the CSO_Pre signal 212-2 can be provided to a second NOR gate. The output of the second NOR gate can be a CSOF signal 213-2. As used herein, the CSEF signal 213-1 and the CSOF signal 213-2 can be used to generate the CSE and CSO signals 227-1, 227-2, respectively. The CSEF signal 213-1 and the CSOF signal 213-2 can be generated using NOR gates. The CSEF signal 213-1 and the CSOF signal 213-2 can be the inverse of what is needed to generate the CSE and CSO signals 227-1, 227-2. The “F” in CSEF and CSOF can designate an inverted signal. The NOT gates are used to invert the CSEF and CSOF signals 213-1, 213-2 into the CSE and CSO signals 227-1, 227-2.

The CSEF signal 213-1 and the CSOF signal 213-2 can be provided to a first NOT gate and a second NOT gate, respectively. The output of the first NOT gate can be a CSE signal 227-1. The output of the second NOT gate can be a CSO signal 227-2.

The CSE signal 227-1 can be an even clock signal. The CSO signal 227-2 can be an odd clock signal. The CSE signal 227-1 can be provided to a delay element 226-1. The CSO signal 227-2 can be provided to a delay element 226-2. The delay elements 226-1, 226-2, 226-3, 226-4 can include hardware configured to delay the CSE signal 227-1 and the CSO signal 227-2.

For example, the delay element 226-1 can delay the CSE signal 227-1. The delay element 226-2 can delay the CSO signal 227-2. The output of the delay elements 226-1, 226-2 can be provided to a NAND gate. The output of the NAND can be provided to a NOT gate. The output of the NOT gate can be provided to the delay element 226-3. The output of the delay element 226-3 can be a clock signal 224-1. The clock signal 224-1 can be provided to the delay element 226-4 and the flip-flop 221-1.

The delay element 226-4 can delay the clock signal 224-1 to generate the clock signal 224-2. The clock signal 224-2 can be delayed as compared to the clock signal 224-1. The delay element 226-4 can correspond to the delay provided by the XOR chain 222. For example, the delay element 226-4 can provide a same delay as the XOR chain 222 provides such that the CAD signals 225 align with the clock signal 224-2 at the flip-flops 221-2.

FIG. 3 is a timing diagram that illustrates data window 332-1, 332-2, 332-3, 332-4, 332-5 in accordance with a number of embodiments of the present disclosure. The data windows 332-1, 332-2, 332-3, 332-4, 332-5 can be referred to as data windows 332. FIG. 3 also shows the CLKE signal 327-1 (e.g., CLKE) and the CLKE signal 327-2, referred to as clock signals 327. The CLKE signals 327-1, 327-2 can be even clock signals. FIG. 3 also includes CSE_EnableF signals 311-1, 311-2. FIG. 3 further includes CA signals 323-1, 323-2, CAxor4 signals 331-1, 331-2, clock signals 324-1, 324-2, and CAD signal 325.

FIG. 3 illustrates the timing of the data windows 332-1, 332-2 relative to the clocks signal 324-1 in previous approaches and the timing of the data windows 332-3,332-4 relative to the clock signals 324-1, 324-2 (e.g., SampleClkD 324-1 and SampleClk 324-2) in a number of examples. The clock signal 324-1 can be analogous to the clock signal 224-2 and the clock signal 324-2 can be analogous to the clock signal 224-1 in FIG. 2B. In previous approaches a clock signal 324-1 can be utilized to sample the CAxor4 signals 331-1. In a number of examples, the clock signals 324-1, 324-2 can be utilized to sample the CAxor4 signals 331-2. As used herein the CAxor4 signals 331-1, 331-2 represent the CA signals 323-2 once they are received at a flip-flop after traversing XOR circuitry also referred to as an XOR chain.

In previous approaches, the clock signal 327-1 can have a 2 tCK transition rate. The CLKE signal 327-1 and the CSE_EnableF signal 311-1 can be used to provide the CA signals 323-1 and to generate the sample clock signal 324-1. The CA signals 323-1 can have a 2 tCK transition rate such that the CA signals 323-1 can be sampled every 2 tCK. The 2 tCK transition rate can result in a 2 tCK data window 332-1 for the CA signals 323-1. The CA signals 323-1 can be provided to an XOR chain. The output of the XOR chain can be the CAxor4 signals 331-1. The CAxor4 signals 331-1 can also have a 2 tCK transition rate which can result in a 2 tCK data window 332-2. The clock signal 324-1 can have a 4 tCK transition rate which may be insufficient to sample the CAxor4 signals 331-1. The skewness of the CAxor4 signals 331-1 as compared to the CA signals 323-1 may further complicate the sampling of the CAxor4 signals 331-1 given that the data window 332-2 does not align with the clock signal 324-1.

In a number of examples, the clock signal 327-2 and the CSE_EnableF signal 311-2 can be used to provide the CA signals 323-2 and to generate the sample clock signal 324-1. The CA signals 323-2 can have a 2 tCK transition rate. The 2 tCK transition rate can result in a 2 tCK data window 332-3 for the CA signals 323-2. The CA signals 323-3 can be latched at a first flip-flop utilizing the clock signal 324-2. The clock signal 324-2 can have a 4 tCK transition rate. The first flip-flop can provide the CAD signals 325 utilizing the clock signal 324-2 such that the CAD signals 325 have a 4 tCK transition rate. The CAD signals 325 can have a data window 332-4 that is congruent with a 4 tCK transition rate.

The CAD signals 325 can be provided to an XOR chain. The output of the XOR chain can be the CAxor4 signals 331-2. The CAxor4 signals 331-2 can continue to have a 4 tCK transition rate with a data window 332-5 congruent with the 4 tCK. The clock signal 324-1 can have a 4 tCK transition rate such that the clock signal 324-1 can be used to successfully sample the CAxor4 signals 331-2. The clock signal 324-1 can be successfully used to sample the CAxor4 signals 331-2 given that the data window 332-5 is congruent with the transition rate of the clock signal 324-1. The clock signal 324-1 can also be successfully used to sample the CAxor4 signals 331-2 because the clock signal 324-1 aligns with the data window 332-5 of the CAxor4 signals 331-2. The clock signal 324-1 aligns with the data window 332-5 of the CAxor4 signals 331-2 because the clock signal 324-1 is offset from the clock signal 324-2 by a same amount as the delay of the XOR chain.

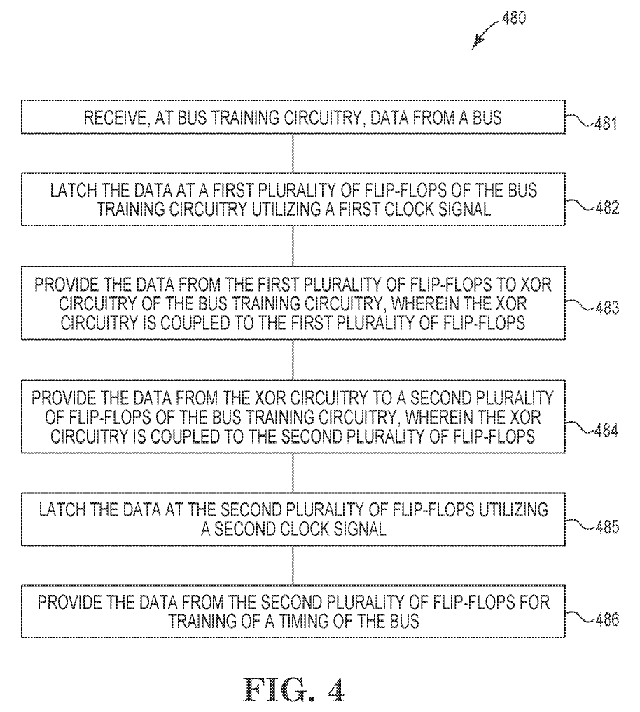

FIG. 4 illustrates an example flow diagram of a method 480 for performing bus training in accordance with a number of embodiments of the present disclosure. The method can be executed by a controller of a memory device of a computing system. The method 480 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 480 is performed by the bus training circuitry 109-1, …, 109-N of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 481, bus training circuitry can receive data from a bus. The bus can couple a memory device to a host system, for example. The bus can be a CA bus or a different type of bus. The bus training circuitry can be implemented in the memory device.

At 482, a first plurality of flip-flops (e.g., flip-flops 221-1 of FIG. 2) of the bus training circuitry (e.g., bus training circuitry 109-1, …, 109-N of FIG. 1) can latch the data utilizing a first clock signal (e.g., clock signal 224-1 of FIG. 2). The first plurality of flip-flops can be DFFs, for example, such that the first plurality of flip-flops utilizes the first clock signal to latch the first plurality of flip-flops.

At 483, the first plurality of flip-flops can provide the data to the XOR circuitry of the bus training circuitry. The first plurality of flip-flops can be coupled to XOR circuitry (e.g., XOR circuitry 222 of FIG. 2). There can be a delay associated with generating an output using the data as an input to the XOR circuitry.

At 484, the XOR circuitry can provide the data to a second plurality of flip-flops (e.g., the plurality of flip-flops 221-2 of FIG. 2) of the bus training circuitry. The XOR circuitry can be coupled to the second plurality of flip-flops. The second plurality of flip-flops can be DFFs. The XOR circuitry can be implemented between the first plurality of flip-flops and the second plurality of flip-flops such that the XOR circuitry receives inputs from the first plurality of flip-flops and provides outputs to the second plurality of flip-flops.

At 485, the second plurality of flip-flops can latch the data utilizing a second clock signal (e.g., clock signals 224-2 of FIG. 2). The second plurality of flip-flops can receive the second clock signal and the data. At 486, the second plurality of flip-flops can provide the data for training of a timing of the bus.

In a number of examples, the second clock signal can be generated using the first clock signal. For example, the first clock signal can be delayed to generate the second clock signal. The delay implemented to delay the second clock signal can correspond to the delay corresponding to the XOR circuitry.

The first plurality of flip-flops can provide the data to the XOR circuitry utilizing the first clock signal. The first clock signal can be utilized to latch the data in the first plurality of flip-flops and to provide the data from the first plurality of flip-flops to the XOR circuitry.

The first clock signal can have a first interval. The first interval can be a transition rate. The second clock signal also has the first interval. For example, the second clock signal can have the same transition rate as the first clock signal. The first interval can be 4 tCK interval. The data received from the bus at the first plurality of flip-flops can have a second interval. The data can be received by the bus, wherein the data has the second interval. The second interval can be a 2 tCK interval, although other intervals can be utilized. The first interval can be twice the second interval among other proportions that can be utilized for the first interval and the second interval.

In various examples, an apparatus can include a bus training circuitry coupled to the bus. The bus training circuitry can include a first plurality of flip-flops, a second plurality of flip-flops, and XOR circuitry coupled to the first plurality of flip-flops and the second plurality of flip-flops.

The bus training circuitry can receive the data from a bus. The bus training circuitry can latch the data at the first plurality of flip-flops. The bus training circuitry can provide the data from the first plurality of flip-flops to the XOR circuitry. The bus training circuitry can provide the data from the XOR circuitry to the second plurality of flip-flops. The bus training circuitry can latch the data at the second plurality of flip-flops. The bus training circuitry can sample the data from the second plurality of flip-flops for training of a timing of the bus.

The first plurality of flip-flops and the second plurality of flip-flops include DFFs. The data received by the bus training circuitry can have a first data window. The data window describes a duration of time in which that data can be accessed. The data can have a data window because the data is received as a signal and the signal can have a transition rate. The data window describes the duration of time between each transition of a signal. The first data window can be 2 tCK. The bus training circuitry can provide the data from the first plurality of flip-flops to the XOR circuitry having a second data window that is wider than the first data window. The second data window can be 4 tCK.

The bus training circuitry can provide the data from the XOR circuitry to the second plurality of flip-flops having the second data window. The signal representing the data as provided from the XOR circuitry to the second plurality of flip-flops can have the second data window. The data can be sampled using the second data window. The bus training circuitry can receive the data from the pads of a memory device.

In a number of examples, bus training circuitry can include a plurality of first delay elements, a second delay element, and a third delay element, wherein the first plurality of delay elements is coupled to the second delay element and the third delay element is coupled to the second delay element. The bus training circuitry can receive a first clock signal and a second clock signal. The first clock signal can be an even clock signal, and the second clock signal can be an odd clock signal.

The bus training circuitry can provide the first clock signal and the second clock signal to the plurality of first delay elements. The bus training circuitry can provide the first clock signal and the second clock signal to a plurality of gates from the plurality of first delay elements. The plurality of gate can include NOT gates and NAND gates. The bus training circuitry can combine the first clock signal and the second clock signal utilizing the plurality of gates. The bus training circuitry can provide a combined clock signal from the plurality of gates to the second delay element.

The bus training circuitry can provide a first clock signal from the second delay element to a first plurality of flip-flops and to a third delay element. The bus training circuitry can provide a second clock signal from the third delay element to a second plurality of flip-flops. The first clock signal and the second clock signal can be utilized by the first plurality of flip-flop and the second plurality of flip-flops to latch data used to train a timing of a bus.

The third delay element can correspond to a delay experienced by the data as the data is processed by XOR circuitry used to sample the data. The first clock signal and the second clock signal can have a same interval. The second clock signal can be delayed as compared to the first clock signal.

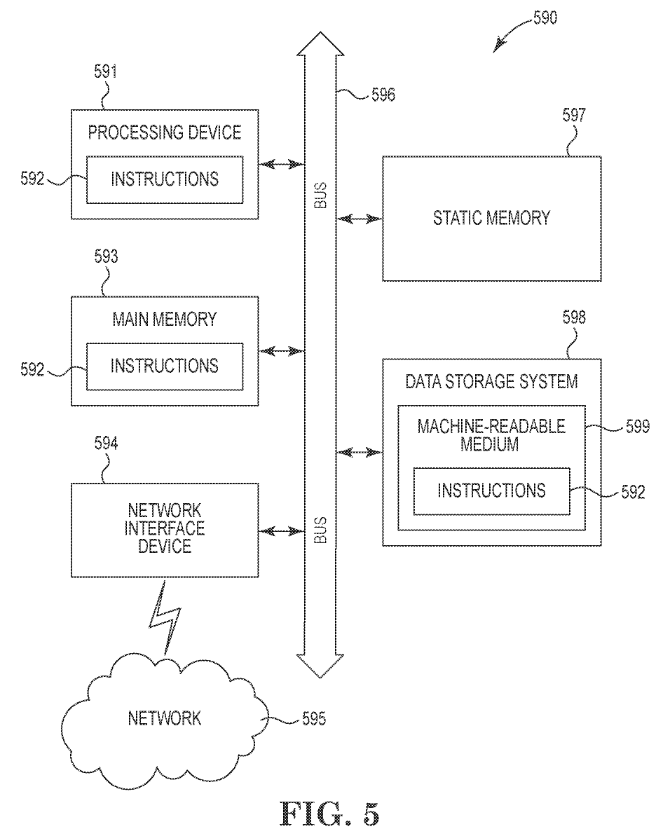

FIG. 5 illustrates an example machine of a computer system 590 within which a set of instructions, for causing the machine to perform any one or more of the methodologies discussed herein, can be executed. In some embodiments, the computer system 590 can correspond to a host system that includes, is coupled to, or utilizes a memory system (e.g., the controller 104 and the memory devices 116-1, …, 116-N of FIG. 1) or can be used to perform the operations of the controller (e.g., the bus training circuitry 109-1, …, 109-N of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 590 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 597 (e.g., flash memory, static random access memory (SRAM), etc.), and a data storage system 598, which communicate with each other via a bus 596.

Processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 590 can further include a network interface device 594 to communicate over the network 595.

The data storage system 598 can include a machine-readable storage medium 599 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 590, the main memory 593 and the processing device 591 also constituting machine-readable storage media.

In one embodiment, the instructions 592 include instructions to implement functionality corresponding to the bus training circuitry 109-1, …., 109-N of FIG. 1. While the machine-readable storage medium 599 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a bus;
bus training circuitry coupled to the bus and comprising:
a first plurality of flip-flops;
a second plurality of flip-flops; and
XOR circuitry coupled to the first plurality of flip-flops and the second plurality of flip-flops;
wherein the bus training circuitry is configured to:
receive data from a bus;
latch the data at the first plurality of flip-flops;
provide the data from the first plurality of flip-flops to the XOR circuitry;
provide the data from the XOR circuitry to the second plurality of flip-flops;
latch the data at the second plurality of flip-flops; and
sample the data from the second plurality of flip-flops for training of a timing of the bus.

2. The apparatus of claim 1, wherein the first plurality of flip-flops and the second plurality of flip-flops include delay flip-flops (DFFs).

3. The apparatus of claim 1, wherein the bus training circuitry is further configured to receive the data having a first data window.

4. The apparatus of claim 3, wherein the first data window is 2 clock cycle time (tCK).

5. The apparatus of claim 3, wherein the bus training circuitry is further configured to provide the data from the first plurality of flip-flops to the XOR circuitry having a second data window that is wider than the first data window.

6. The apparatus of claim 5, wherein the second data window is 4 clock cycle time (tCK).

7. The apparatus of claim 5, wherein the bus training circuitry is further configured to provide the data from the XOR circuitry to the second plurality of flip-flops having the second data window.

8. The apparatus of claim 5, wherein the data is sampled using the second data window.

9. The apparatus of claim 1, wherein the bus training circuitry is configured to receive the data from pads of a memory device.

10. A method, comprising:
receiving, at bus training circuitry, data from a bus;
latching the data at a first plurality of flip-flops of the bus training circuitry utilizing a first clock signal;
providing the data from the first plurality of flip-flops to XOR circuitry of the bus training circuitry, wherein the XOR circuitry is coupled to the first plurality of flip-flops;
providing the data from the XOR circuitry to a second plurality of flip-flops of the bus training circuitry, wherein the XOR circuitry is coupled to the second plurality of flip-flops;
latching the data at the second plurality of flip-flops utilizing a second clock signal; and
providing the data from the second plurality of flip-flops for training of a timing of the bus.

11. The method of claim 10, further comprising generating the second clock signal utilizing the first clock signal.

12. The method of claim 10, further comprising providing the data from the first plurality of flip-flops to the XOR circuitry utilizing the first clock signal.

13. The method of claim 10, wherein the first clock signal has a first interval.

14. The method of claim 13, wherein the second clock signal has the first interval.

15. The method of claim 14, wherein the first interval is a 4 clock cycle time (tCK) interval.

16. The method of claim 14, wherein the data is received from the bus at the first plurality of flip-flops has a second interval.

17. The method of claim 16, wherein the second interval is a 2 clock cycle time (tCK) interval.

18. An apparatus, comprising:
bus training circuitry coupled to a bus and comprising:
a plurality of first delay elements;
a second delay element; and
a third delay element, wherein the plurality of first delay elements are coupled to the second delay element and the third delay element is coupled to the second delay element;
wherein the bus training circuitry is configured to:
receive a first clock signal and a second clock signal, wherein the first clock signal is an even clock signal and the second clock signal is an odd clock signal;
provide the first clock signal and the second clock signal to the plurality of first delay elements;
provide the first clock signal and the second clock signal to a plurality of gates from the plurality of first delay elements;
combine the first clock signal and the second clock signal utilizing the plurality of gates;
provide a combined clock signal from the plurality of gates to the second delay element;
provide a first clock signal from the second delay element to a first plurality of flip-flops and to a third delay element;
provide a second clock signal from the third delay element to a second plurality of flip-flops; and
wherein the first clock signal and the second clock signal are utilized by the first plurality of flip-flops and the second plurality of flip-flops to latch data used to train a timing of a bus.

19. The apparatus of claim 18, wherein the third delay element corresponds to a delay experienced by the data as the data is processed by XOR circuitry.

20. The apparatus of claim 18, wherein the first clock signal and the second clock signal have a same interval.
